(19) United States
(12) Patent Application Publication
(10) Pub. No.: US 2013/0305520 A1
(43) Pub. Date: Nov. 21, 2013

(54) Batch Manufacturing Meso Devices on flexible substrates

(71) Applicant: Trevor Graham Niblock, Agoura Hills, CA (US)

(72) Inventor: Trevor Graham Niblock, Agoura Hills, CA (US)

(21) Appl. No.: 13/476,004

(22) Filed: May 20, 2012

(51) Int. Cl. G01R 3/00; G06F 17/50

(52) U.S. Cl. 29/595; 716/119

(57) ABSTRACT

This invention provides a method of fabricating transduction devices on flexible electronics that allows a complete mechatronic system to be incorporated into one system. The method uses the interconnects and pads in flexible electronics substrates to make coils, windings and electrodes for electromagnetic and electrostatic transduction. By building these systems directly into the substrate it is possible to make a complete sensing and actuating system that can be fitted onto machinery that requires power and control. The end result is a flexible, 3-dimensional structure that contains transduction, power, and control interconnections, and is customized for complex mechatronic structures and applications. This gives designers of electromechanical control systems the ability to produce a complete feedback system with sensors, actuators, connectors and electronics; all made out of one component.

### FIELD OF THE INVENTION

The invention relates to the field of MEMS, flexible electronics and system-level integration of mechatronics. More particularly, this invention relates to layered manufacturing of transducers using MEMS fabrication techniques and additionally using features of flexible electronics to make three-dimensional transducers.

### BACKGROUND OF THE INVENTION

One of the challenges in designing complex electro-mechanical systems (mechatronics) that have numerous components, connections, and communications lines is optimizing these parts to the full potential of the dynamic range of available transduction. If a commercial, off-the-shelf (COTS) strain gauge with a full dynamic range of 1000 μStrain is chosen for a particular design, and then only used to measure a maximum of 10 μstrain, it implies a 2 orders-of-magnitude sub-optimal resolution. This is a common problem with traditional methods of sensor and actuator system design and fabrication as COTS components make the necessary customization of all components prohibitively difficult. Thus, a method is needed that allows the designer to simply ‘drop’ components from a library directly into a system at the desired location and have it scale to optimal performance for that application.

This invention provides a solution to the needed method. It is a complete system; it has sensors, connectors and wiring to a main controller (or communications module). The method shown in this invention allows building a system that encompasses sensors and actuators, their interface to communications and power lines, and the power and control logic on the other end of these lines. Traditional methods to date have only used individual components.

A traditional method of building a control system with sensors and logic is given by Wells (2011/0071675). However this is a description of a control system and the modules used in the system as opposed to a unique method of building the physical hardware (which is presented in the current invention).

Jenner (2007/0285040) and Solomon (2004/0030451) describe the concepts of a nervous system design for individual and swarm robotics. This is an example of a widely used robotic control systems. These systems are descriptions of software models for mounting onto the hardware systems that are presented in the current invention but do not in themselves offer a manufacturing solution.

Hence, when considering prior art individual devices will be examined. The architecture of these devices will be similar or analogous to what is presented in the current invention to produce a complete mechatronics system. A trend that is seen in this prior art and indeed in the MEMS, flexible and organic electronics fields is a tendency for specializing and more precisely developing unique and differentiable methods of fabrication. Hence, the transducers and systems become more unique/discreet and less easily integrated into a system during their fabrication.

To begin reviewing the related art, devices on silicon (mainly MEMS) and flexible substrates and will be examined. In practice, although a significant amount of work has gone into the development of systems and components for flexible electronics (i.e. organic electronics), none have looked at using flexible electronics as a substrate for building mechatronic devices in the way silicon has been treated as the substrate for building most MEMS devices; this is a key concept of this invention.

Devices made according to this invention, and traditional MEMS and semiconductor devices, share the concept of layered manufacturing.

Traditional methods of (MEMS) transducer manufacture use processes such as sputtering, plating, or spinning to deposit layers that are then defined by some form of photolithography or direct write. Examples of the substrate and MEMS layered manufacturing are given in the patents by Lee (1999, U.S. Pat. No. 5,953,622), Kai (1999, U.S. Pat. No. 5,899,743), Stouppe (1997/U.S. Pat. No. 5,662,771) and Diep (2008, U.S. Pat. No. 7,378,293 B2). They give methods of joining wafers to form an SOI wafer, pre-processing of silicon to form an ideal substrate (good for both electronics and MEMS devices), a method of building layers to make a surface micro machined device and a hybrid method of making MEMS devices by partially making the device on silicon and then bonding a pre-micromachined cover (can be silicon or quarts) respectively. The reasons these four examples have been chosen of MEMS substrate and device fabrication from the myriad of available IP in this area is that they are both analogous to the technology in the current invention whilst at the same time highlight the deficiencies of the technology. Starting with Lee (1999, U.S. Pat. No. 5,953,622); the current invention also binds layers of what is effectively substrate to form the top and bottom of a device, the difference being that this invention allows for many different substrates to be bounded with many methods of adhesion whilst Lee is limited to Silicon and the fabrication methods available to machine silicone. The end effect is the same, a layered device material that can be formed through photolithography, etching and plating into many different sensors and actuators. However, our system can interface with silicon (and all its well established processing methods), Polyimide, inkjet deposited organic electronics and a host of photo chemically etched metal shims.

Kai (1999, U.S. Pat. No. 5,899,743) emphasizes that the silicon substrate is dual use; the end result is a ‘highly polished semiconducting wafer’ that can be used for both electronics and MEMS applications. Likewise, in the current invention it is implied that COTS flexible electronics can be used in exactly the same way; one can flip-chip bound a multitude of substrates on to the flexible electronics. These substrates can include silicon if electronics are required, or organic materials can be used for electronics and our method of sensor fabrication can be used for transduction.

The previous two patents cover layered manufacture. Hence, when considering the technology being put forward in the current invention the comparison between surface and bulk micro/meso/macro machined devices needs to be empathized. To look at analogies between the process being put forward in the current invention and that of surface micromachining it is best to refer to the ADI patent by Stouppe (1997/U.S. Pat. No. 5,662,771), this is a method of polysilicon deposition on oxide, patterning the poly, etch, and then release to produce a fine mechanical structure with conducting properties (probably used for a comb drive accelerometer like the AD50XL). These processes are directly transferable to flexible substrates; the materials that are used need to be changed and (at this point our technologies development) feature sizes are an order of magnitude larger. The basic principle and sequence of device fabrication however is the same; it is the handle (substrate) and materials that have changed. In the case of the current invention, the sacrificial oxide would be replaced with a (e.g.) polymer and the polysilicon actuator would be made from (e.g.) electroplated nickel.

For bulk micro machining, rather than a wet (KOH) or dry (DRIE) etch, laser or mechanical milling would be used, and as the substrate is Polyimide the same results as Zavracky (1992/U.S. Pat. No. 5,095,401) can be achieved by pre-machining the flexible substrate(s) and bonding to form cavities, orifices and actuation gaps. Note that either wet or reactive ion etching could still be used in the current invention as a method of material removal with a photolithographic mask.

The transduction devices that our process enables' are similar to those produced in MEMS with the transduction being electrostatic or magnetic, and movement being normal (Niblock U.S. Pat. No. 7,464,459) or in the plane (Niblock U.S. Pat. No. 7,602,267) of the substrate. Tamura (2003/0156451) and Ben-Gad (2005/0018322) also give good examples of how magnetics can be used to give in-plane and out-of-plane actuation, respectively. These systems could be used for sensing, and both are directly transferable to a flexible substrate. Electrostatics is not as easily transferable due to actuation gapsⁱⁱ, hence, the electrodes would need to be increased in size if devices like those proposed by Moidu (2011/0140569) and Sinclair (2007/0158767) where to be used; these are in-plane and out-of-plane actuators, respectively. They could be manufactured in flexible electronics; however, they would require large driving voltages if actuation gaps where to be scaled. Nonetheless they can be used for sensing.

As with MEMS and semiconductor devices, using a flexible electronics substrate and photolithography in combination with sputtering, plating and etching it is possible to get fine features in the plane of the substrate. Layer thickness can be controlled in the sub-micron range. Once again there is a myriad of prior art that could be referenced of how to make MEMS devices using these techniques. The solution put forward in the current invention is hence unique in that it allows for these fabrication methodologies to be realized in alternate materials; a concept that hitherto has been missing in MEMS as few if any have made the jump from semiconductors as substrates.

The present method of design for complex mechatronic systems is to identify/conceive the greater structure and then add on the finer detail. This is perfectly logical as it would be impractical to design the ‘shoe’ without first conceiving the ‘foot, leg or body’. Hence, the physical structure is designed and items such as sensors, connectors, housings and wires are ‘added’ as the structure is developed to meet the design criteria. Taking a humanoid robot as an example, the engineer/designer would initially (e.g.) work out how big the device should be to lift the required weight. The actuators and sensors for force feedback and actuator control would then be added as the design becomes more complex. Additional components would then be added to interconnect the expanding network of sensors and actuators, further complicating the design.

The design process as performed today assumes that all the components used in making the structure (e.g. the robot) are discreet. Indeed, all the components in the sensor and actuator system tend to be discreet. Hence, each sensor is made up of the sensor, the package, and interfaced using a ‘connector’. This connector interfaces to a wire or wire bus that connects at the other end to another connector and the control ‘box’. Modern CAD systems accommodate for this method of design by allowing for assemblies and sub-assemblies that simulate the connection using some form of markup language (e.g. XML). In this manner if sensing or actuation is required at a location on the model, a device can effectively be bolted on and connected both in the CAD model and in real space when the device is fabricated.

Using this method of design and fabrication, transducers are ‘bolted’ onto the system which are usually COTS components. At best, the correct size and shape sensor is chosen. However, it is seldom that each sensor is custom-made for the design to operate at its full band width (optimum). Yet operating at full band width is preferable in order for the device to offer the maximum fidelity over its full range while minimizing factors such as weight and power (hence cost).

Hence, the present method of manufacturing mechatronic devices produces complex systems that are generally labor intensive to fabricate with a myriad of parts that require expertise both in design and fabrication. The level of complexity makes the devices expensive and also prone to failure.

There is therefore a need for a system that can be simply designed and incorporates the sensor, connector, wiring and control on the same platform. To be effective, this platform needs to be scalable and allow for changes further down the design path time line. This invention is for such a system; aimed at providing exactly this solution to the designer.

### SUMMARY OF THE INVENTION

The invention provides systems and methods for batch manufacturing of sensors and actuators and the BUS system that connects them to electronics and one-another as a single device/system.

In a preferable embodiment of the invention, would be for the control system for a robot whereby the system would provide the sensors and actuators and have all the control electronics mounted directly onto the flexible electronics substrate.

Another embodiment of the system would be for the feedback control system of a UAV (Unmanned Aerial Vehicle). Whereby the system would provide the sensing for aileron pitch, a magnetic compass and undercarriage location as well as actuation for optics whilst connecting all systems to the central controller.

In accordance with one aspect of the invention the system provides a method for the fabrication of embedded sensors by stacking layers of flexible electronics upon one another to form the sensors.

In accordance with another aspect of the invention the layers can interact through electro magnetics allowing for sensing or actuation.

In accordance with another aspect of the invention the layers can interact through electro statics allowing for sensing or actuation.

In accordance with another aspect of the invention multiple devices and system can be mounted onto the same piece of flexible electronics which can be folded where necessary.

In accordance with another aspect of the invention different sections of flexible electronics can be stacked

In accordance with another aspect of the invention 3^{rd} party (COTS) devices can be added to the flexible electronics to make a complete system with the embedded sensors.

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments. For each aspect of the invention, many variations are possible as suggested herein that are known to those of ordinary skill in the art. A variety of changes and modifications can be made within the scope of the invention without departing from the spirit thereof.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIGS. 1 through 4 show the process that goes from generating a tranducer design to extracting a flexible electronics blank; in this case the transducer is a magnetically actuated robot arm.

FIG. 1 shows a magnetic core that is used as the building block for the transducer

FIG. 2 shows the complete transducer with 3 sets of cores layered 3 high.

FIG. 3 shows only the flexible electronics component (no core) of the transducer in 3D.

FIG. 4 shows flexible electronics component of the transducer in flat pannel form.

FIG. 5 shows an inductor made by wrapping flexible electronics containing tracks and bound pads around a photochemically-etched permalloy core.

FIG. 6: shows planar coils that can be used with or without a soft magnetic core

FIG. 7 shows a printed coil winding on flexible electronics

FIG. 8: shows an electroplated core

FIG. 9: shows a pre-machined core mounted on a flexible substrate

FIG. 10: shows electrostatic transducers using opposed sets of electrodes by ‘bending’ the flexible electronics substrate

FIG. 11 shows a complete magnetic actuation and electrostatic sensing system comprising a plurality of arrayed devices on a flexible substrate.

### DETAILED DESCRIPTION OF THE INVENTION

While preferable embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention.

The invention provides systems and methods for batch manufacturing of transducers using flexible substrates. The transducers may be used in any application, including, but not limited to, complex mechatronic systems that may be required to be low cost, lightweight, and easily reproduced. For example, in a robotics application, close proximity force (touch) sensing is required in conjunction with fine control actuation and a medium to respectively relay the signals and driving electronics to and from the controlling electronics. Thus, transducers processed using flexible substrates may be used in any type of electric machine or electric/electronic device application.

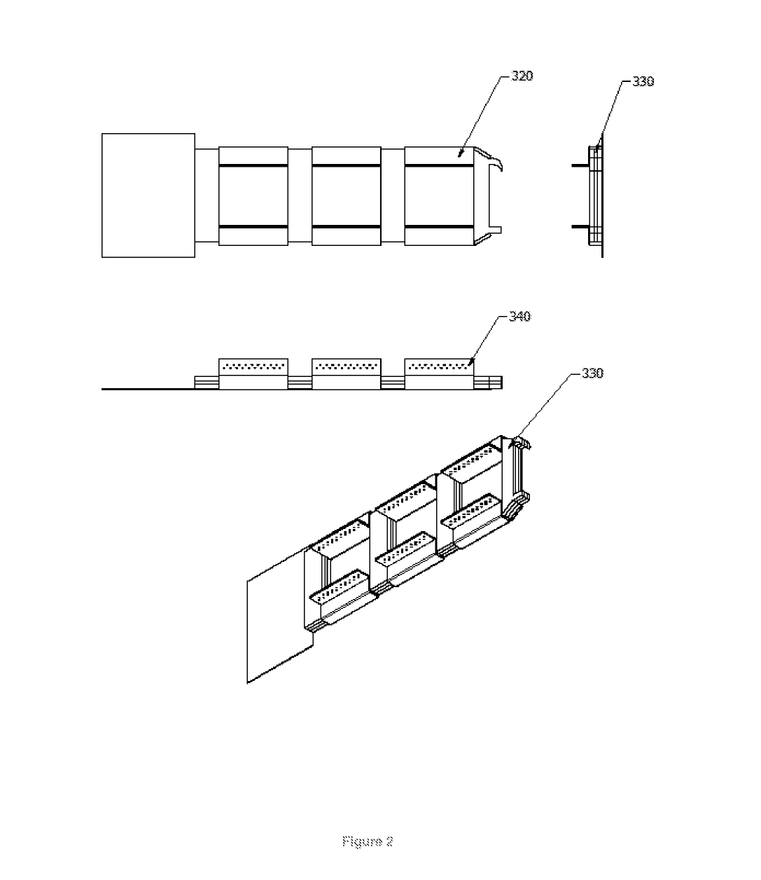

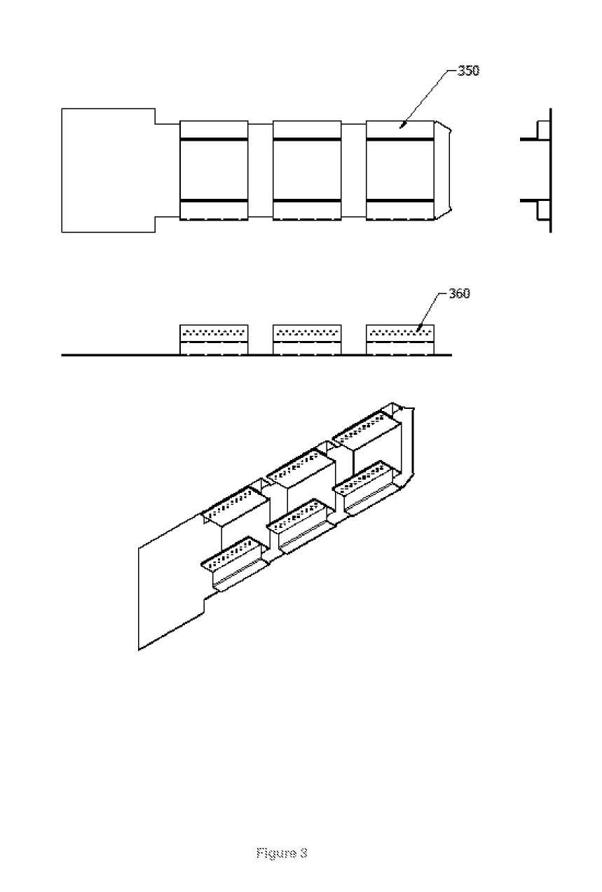

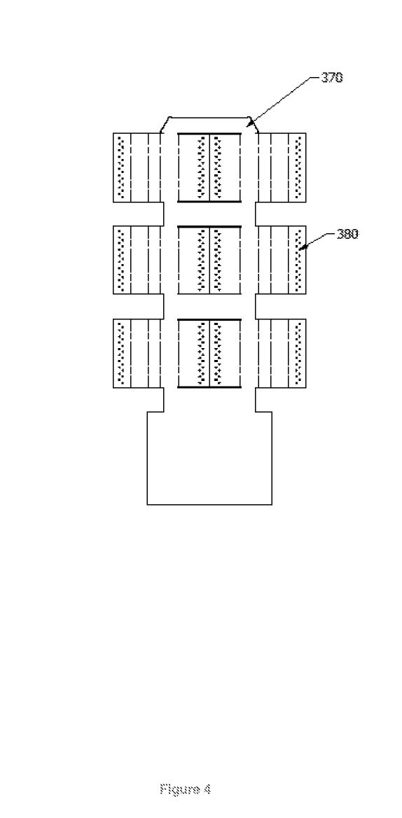

FIG. 2 shows a magnetically-actuated robot limb made from flexible electronics. In FIG. 3 the blank flexible electronics panel from which the limb is constructed is shown in its wrapped 3D state whilst in FIG. 4 the un-wrapped or flat panel version is shown. Note this is actually a post-processed section of flexible electronics design. I.E. it has been processed in a PCB layout editor that has imported the panel with all blank panel data (i.e. edges and vias) and defined the tracks and vias that will make up the winding around the magnetic core.

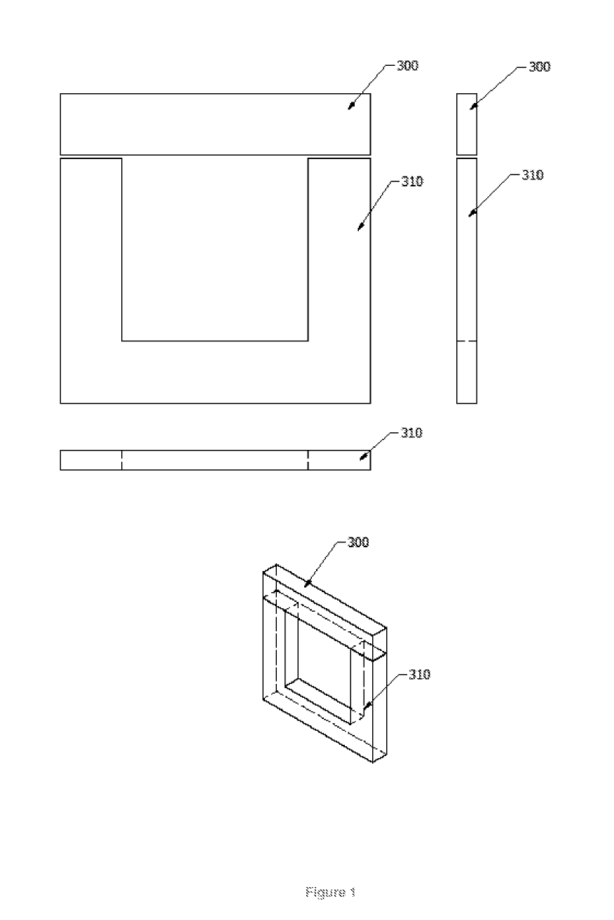

Initially the device is designed in a standard 3D CAD environment. The process begins by designing the actuator core; in this case a Permalloy panel (˜1 mm thick) is photochemically etched to form a soft magnetic core (FIG. 1) 310 with a stator 300. The core in FIG. 1 then shown in FIG. 2 staked 3 layers high 330 and wrapped with the panel (˜100 μm flexible electronics) 320 to produce a limb. The panel 320 in FIG. 2 has vias in it that are used for alignment later in processing.

FIG. 3 shows this panel 350 with the vias 360 on its own still in 3D.

FIG. 4 shows the panel 370 after it has been extracted from the CAD software as a flat panel or blank; it still has the vias 380.

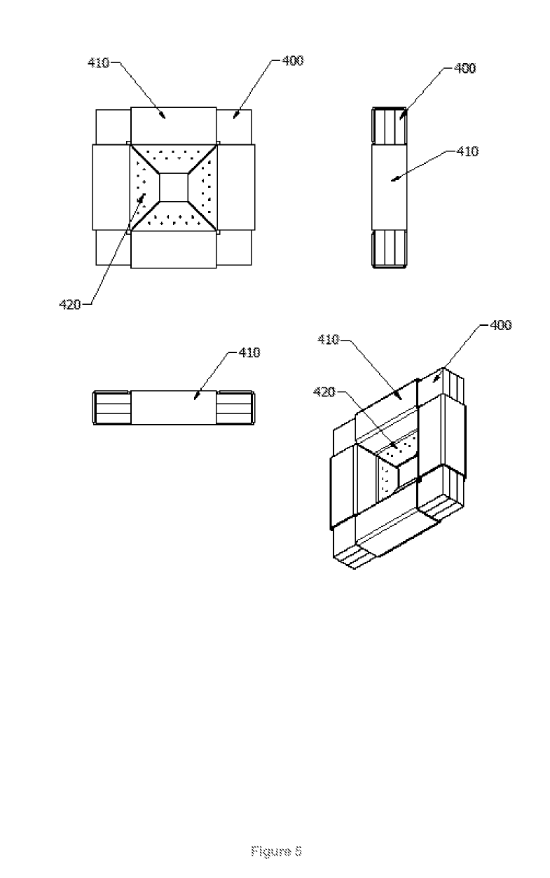

The same process can be used to manufacture a host of devices with electromagnetic and electrostatic transduction. FIG. 5 shows one particular example of a component made using this process—an inductor—with the flexible electronics 410, the magnetic core 400 and the vias 420.

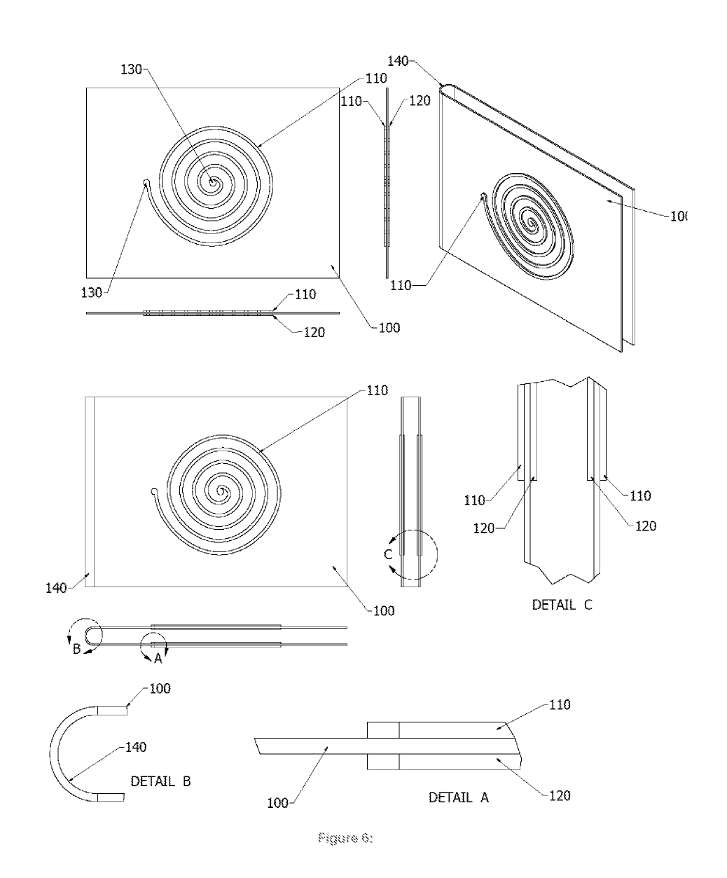

FIG. 6 illustrates one embodiment of the invention where the magnetic transduction device coils 110 and 120 that are planar. The magnetic transduction device 110 is photochemically defined on a flexible electronics substrate 100. When the substrate (which can be polyester (PET), polyimide (PI), polyethylene napthalate (PEN), Polyetherimide (PEI), along with various fluropolymers (FEP) and copolymers Polyimide films or any other insulating material with a degree of flexibility) has two or more metal (interconnect) layers, these planar coils can be wound on both sides (110 top & 120 bottom) of the substrate and connected using a via 130. By placing a fold in the substrate 140, sets of coils (FIG. 6 detail C) can be placed opposite one another and according to the current direction in the coils made to attract or repel.

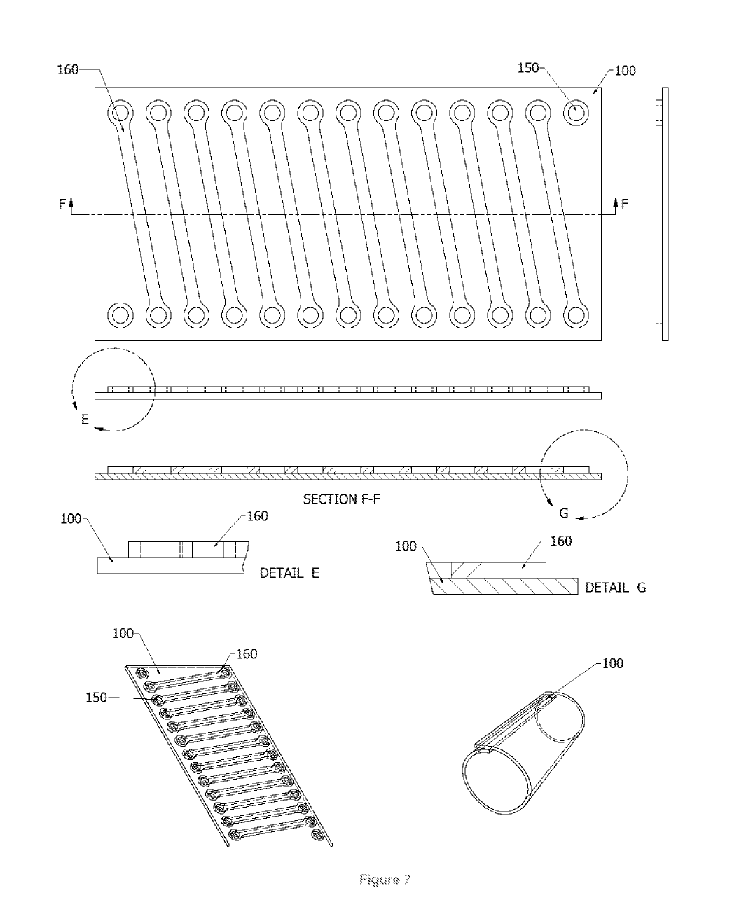

Referencing FIG. 7, coil windings can be fabricated by producing sets of tracks 160 on the substrate 100 with vias that align when the substrate is rolled into a tube (bottom right of FIG. 7, 100).

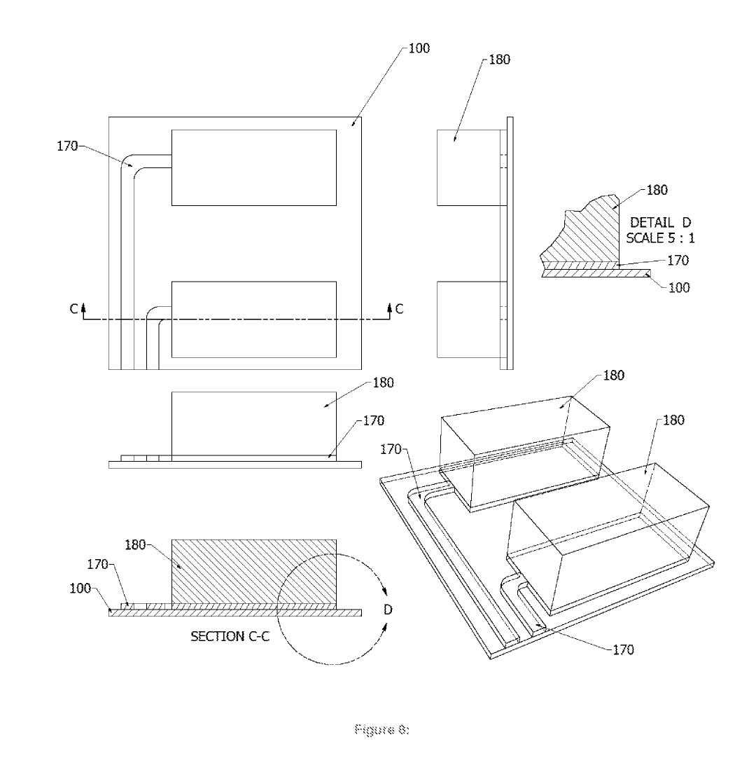

Referencing FIG. 8 a magnetic core can be used to enhance the performance/transduction of a device. It can be electroplated onto the flexible electronics substrate 100 by having exposed plating sites 170. The sites 170 can either be directly plated onto or masked off to form a mold into which the material is plated.

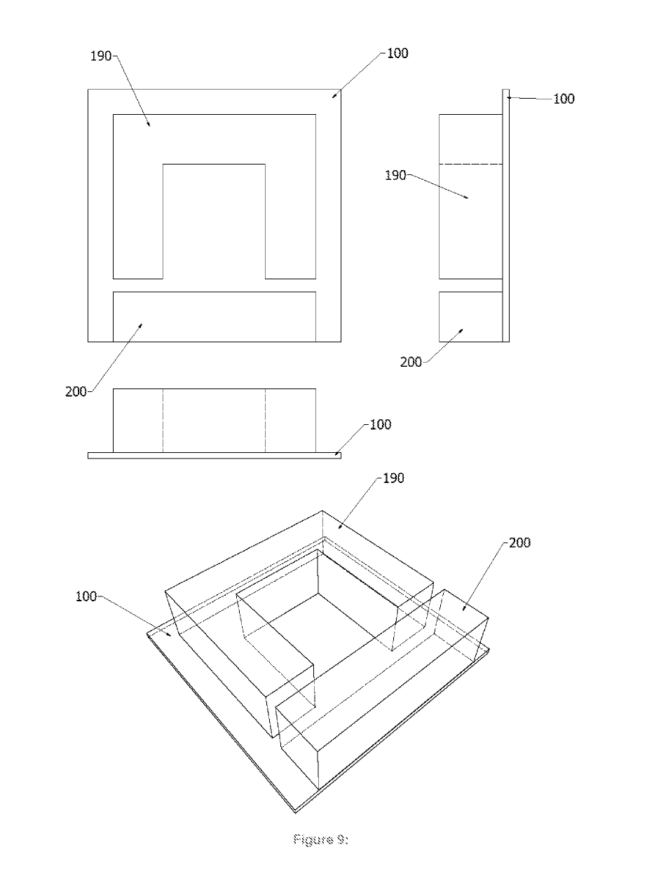

Referencing FIG. 9 an alternative method of forming a magnetic core to enhance transduction, is to have the core (190, 200) machined using a conventional method (e.g. milling, wire electro-chemical machining or photo-chemically etching) and then mounting it onto the flexible electronics substrate 100.

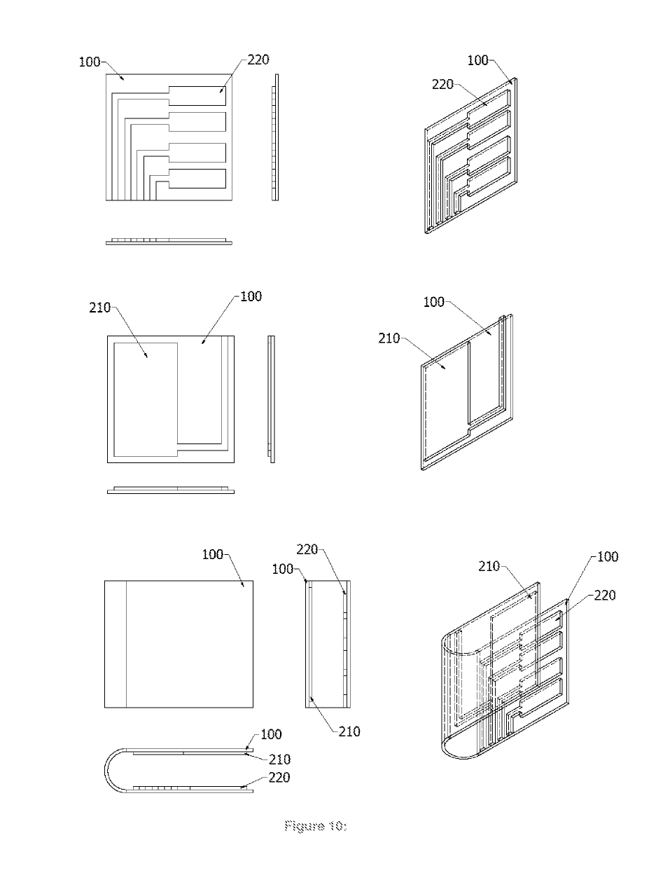

FIG. 10 illustrates another use of the invention to achieve an alternative method of transduction using electrostatics. Electrodes can be defined on the flexible electronics substrate 100. In this case a common electrode 210 is patterned along with an array of smaller electrodes 220 patterned so that the flexible electronic substrate, can be bent such that each set of electrodes is opposed to one another. Such a system can be used for sensing and actuation. Note that a dielectric layer on top of the electrodes is not shown.

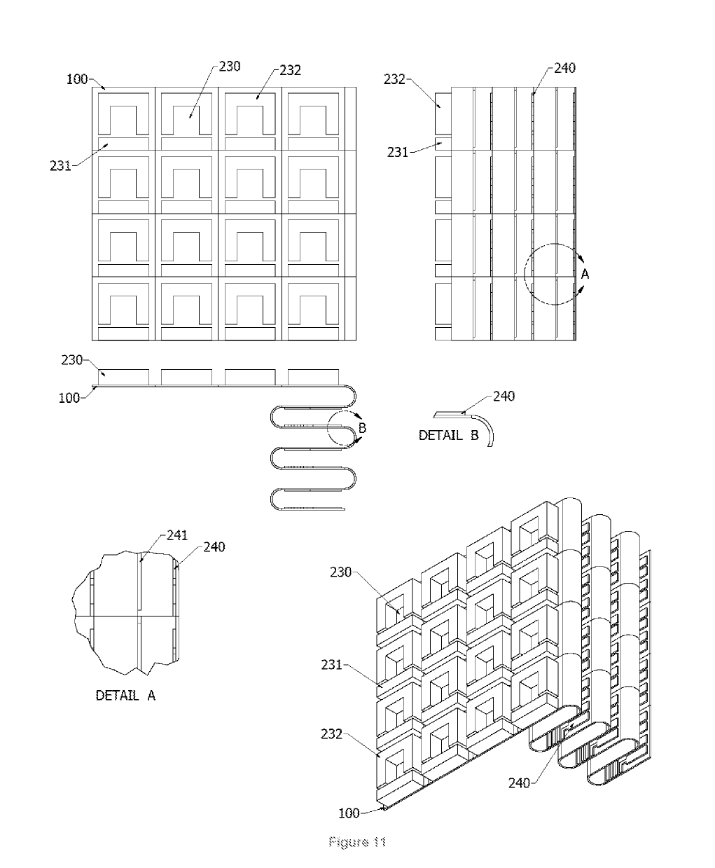

Referencing FIG. 11, by combining arrays of devices on the flexible electronics 100, complete system can be made to both actuate 230 or sense 240. The flexible electronics can also be used for its more conventional use of power and data transfer, PCB interface, IC mounting and (electronics) device interface.

### DETAILED DESCRIPTION

One embodiment of the invention is to use MEMS fabrication techniques on-top of a flexible electronics base to produce a selection of transduction devices that are pre-mounted onto a physical power and communications bus (i.e. the flexible substrate). The concept allows for processing directly on the flexible substrate, or process separately and then mounting the pre-processed component onto the pre-machined flexible electronics base. The flexible electronics itself offers (e.g.) the sensing element, the physical interface (connector), the wiring (interconnect) and allows direct connection to a power supply or controller unit.

By using the flexible electronics substrate, photolithography, and various deposition techniques, a large array of MEMS-type transducers can be madeⁱⁱⁱ. Devices need not only be formed by photolithography but can be printed or formed using many processes. These processes can be; inkjet or contact printing, nano-imprinting, and organic electronics laser transfer printing. Other pattern transfer methods such as gravure, hot embossing, vapor-phase printing, and laser processing (cutting, sintering, patterning) can also be used. To define structures and patterns of complete systems (transducer, interconnect and power/control system) methods such as stamping, mechanical and laser routing can be used. Layers can be applied using processes such as slot-, dip- and spray-coating the flexible electronics. Layers can also be built by simply stacking the two or more sections of processed flexible electronics upon one another. Reel to reel techniques for photolithography, electroplating, nano-imprinting and laminate layers can also be used to fabricate and build up stacked systems.

Using the above techniques it is possible to manufacture a host of devices on a single flexible electronics substrate: many of these devices being well established MEMS as well as macro mechanical designs. A key element of the concept is that devices and systems are no longer limited to being planar. This is because unlike, a silicon substrate, flexible electronics can be bent and folded, hence it can be engineered to encapsulate bulk materials such as magnetic cores or even designed to sit on-top (or inside) of a 3D structure that needs to be transduced (actuated or sensed), as shown for the robot arm in FIG. 2.

A major challenge in designing a system such as the one being proposed in the current invention is generating the blank (2D) flexible electronics panel used to make the complex 3D structures and system with all the interconnects and bulk components needed to service a complex mechatronics systems such as (e.g.) a robot arm. The tool that has been used to achieve this is a ‘standard’ commercial mechanical CAD package: In most COTS 3D mechanical CAD packages (AutoDesk Inventor, Solidworks . . . ) a Sheet Metal Design Module is available. As the name suggests this CAD software module is used by the design engineer to wrap a single virtual piece of sheet metal around a 3D object (including a 3D volume of air), and then extract the virtual flat sheet metal from which the real sheet metal is made. Sheet Metal Design Modules are not designed for flexible electronics layout; they are used for designing 3D casing or boxes. The invention takes advantage of Sheet Metal Design Module features to produce complex 3D structures using flexible electronics in place of sheet metal. FIG. 1 through FIG. 4 show the invention method using Sheet Metal Design Modules as applied to flexible electronics. FIG. 4 shows the flat flexible electronics panel. FIG. 3 shows the folding necessary to “wrap” the panel around the core (here, shown without the core). FIG. 1 shows the core. FIG. 2 shows the complete system: the panel wrapped around the core. The flat panel in FIG. 4 is exported to a standard PCB layout editor, where tracks, mounting pads, windows, and vias are placed.

Hence, a key concept of the current invention is to integrate (mainly) MEMS transduction techniques with the capabilities of 3D-CAD sheet-metal forming (for flexible electronics) to create an easy design path for flexible electronics batch manufacture. This allows for the fabrication of MEMS-type devices with more complexity and capability and furthermore allows for the fabrication of complete systems from one section of flexible electronics. As a vehicle to show how the system works, the two examples of a sensor and actuator given in the peer reviewed paper “Batch Manufacturing of MEMS devices on Flexible Substratesⁱⁱⁱ” are now covered. These (relatively simple) example devices are given to show the concept of how one can go from transducer conception through to creation on a flexible substrate; by definition, the fact that these devices are fabricated on flexible electronics means that they can be stacked and/or placed on another section of flexible electronics that also acts as the wiring bus to any signal conditioning and control system such as an MCU (also mounted on the flexible electronics).

Referring to the magnetic actuator in the paperⁱⁱⁱ, flexible electronics are ‘wrapped’ around the magnetic core to form a winding that generates a magnetic potential (h). This is done by firstly modeling the core(s) of the system in 3D CAD. In this example the tool used is AutoDesk Inventor, but other COTS packages such as Solidworks, Catia and ProEngineer would work just as well. In this case the core was made by electro-chemically etching Permalloy shim. Hence, the drawing from which the core was extracted into 3D is also exported (as a .dxf) file to form the mask used in the photo lithography process that produces the core, as in the device shown in FIG. 9.

Using the sheet metal module, the core(s) is wrapped with the flexible electronics (as in FIG. 5). Bend and corner radii are all pre-defined in the software for the flexible electronics (as they would be with sheet metal). Once the 3D CAD model is made the panel is extracted to 2D and exported (as a *.dxf file) to an electronic layout editor. Actual and virtual features such as wiring connections and weight are attached to the file in the 3D CAD model to allow auto-routing of tracks. These features can be pad numbers and bus descriptions as well as holes for vias and the tracks themselves. All of this can be done manually, however a properly configured auto-router will do the job in seconds rather than hours for larger modes such as the one presented.

Whilst in the 3D CAD environment the assembly jigs that will be used to fabricate the devices can also be designed. In this case the finished models of the jigs can be exported as standard CAM files and machined on macro CNCs machining centers. Note, in the case of the Micro robot arm for this example, although the feature sizes are in the micron range the tolerance on the assembly jig need only be in the tens of micron range, hence most all jig components can be macro machined.

Assembly is achieved by placing the flexible electronics onto the jig, mounting the photochemically etched Permalloy core onto the flexible electronics and bending the flexible electronics around the core. Binding the system can be done manually or using reflow. In this case the design gives multi-limb actuators with an interface that can connect directly to an MCU on the same piece of flexible electronics (assuming the MCU has a DAC that can source the current to generate sufficient magnetic potential (h) around the core for the application).

Hence, all components are COTS: the CAD environment used to design the system, the photolithography used to produce the permalloy core and flexible electronics substrate, and the CAM and macro machine used to make the assembly jig.

The second device in the paperⁱⁱⁱ (and on the same flexible electronics substrate) is a pressure sensor. It is designed in a CAD environment and requires no assembly jig and external components. The design is an array of 16 (4×4) pads wired next to a pad of a similar area to that of the array. The thickness of the cover coat on the larger and arrayed pads can be changed by forming a grid or specifying a particular thickness. By folding the larger pad over the smaller ones a series of electrostatic sensors is formed; essentially an array of capacitors with a common ground (the larger pad). This example was used to measure bite pressure for dental applications, hence a relatively thick covercoat with no grid gaps was specified, allowing a force of up to 250 N cm⁻² to be measured.

The manufacturing process presented in the current invention is designed to make not only the transducer but a complete mechatronic system. It is aimed at assemblies such as those one would find in robotics and machine control. The process allows for a customized system that include sensors and actuators, their interconnections and (where necessary) the logic that accompanies them. By offering a method of transduction fabrication on the flexible electronics the proposed invention allows all these systems to be manufactured as one component or assembly.

A robotic limb will be used to show how the system would be utilized. Such a (mechatronic) system requires many components that all need to interact. Considering the end effector (hand), a significant amount of feedback needs to be measured through pressure (touch), and each finger will require a set of actuators. The, wrist and forearm will need power actuators and the total force in these limbs will need to be measured via (e.g.) strain.

Hence, to design a robot arm an engineer presently needs to select a set of pressure sensors for the hand and strain gauges for the arms. They will also need to select the actuators for the hands and arm. The next task would be placement of the sensors and actuators on the model (in CAD) and then work on the connections and wiring. A (local) MCU would likely be used to work out local feedback loops in the end effector for picking things up. Hence, wiring, power and a global and local bus system would need to be devised. The different components of the design would all need to be machined and assembled as required with the final mechatronic system also requiring highly skilled technical assembly.

Using the system of design and fabrication presented in the current invention, the larger actuators and MCU would still have to be COTS components and the machining/assembly of the main structure (mechanical frame) would still remain unchanged. However, placing and wiring the sensors and actuators on the fingers, hand, and arm; and connecting the system power and bus together can all be accomplished using the invention of fabricating sensors directly out of the flexible electronics followed by transducer and trace/track/bus auto-routing (any local integrated circuits (ICs) can be reflowed directly onto the flexible electronics). In this case the sheet(s) may be wrapped both inside and outside of the arm structure to provide sufficient sensing and communications. Also, by being able to place a selection of electromagnetic and electrostatic transducers as described above a significant amount of the transduction can be built into the flexible electronics.

For the designer this reduces the complexity of design significantly as devices can be selected from a drop-down menu. Additionally, by effectively reducing the number of components and their interfaces the system is more robust and significantly cheaper.

A preferred embodiment of the invention comprises a system containing a library of transduction components pre-designed in a CAD package. These predesigned devices can be parameterized for maximum performance over a range of physical phenomena. In this manner an engineer could design the mechatronic device they are making and place the transducers in a desired location selecting the range of transduction the transducer should work in. The system would automatically scale the transducers for optimized performance for the particular location and applications. By using a sheet (metal) module the engineer can connect all the transduction devices and systems in the assembly onto the same piece of flexible electronics.

Exporting the extracted flat panel to a layout editor, it is then possible to automatically connect all components and produce the flexible electronics panel that will provide the control and power connections and a host of embedded sensors across the assembly.

Significantly, those transducers that it isn't possible to assemble as part of the flexible electronics system, due to constraints such as fidelity, complexity or semiconducting properties, can also be connected to the flexible electronics (e.g. reflowed) as discreet components.

As the organic and inkjet electronics industry evolves, the amount and type of modules that can be built and stored in the CAD library will continue to increase making the array of transducers that can be fabricated by this method an ever increasing list.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of embodiments of the invention herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

1. A method for fabricating electrostatic and electromagnetic transducers comprising:
Providing a flexible electronics substrate;
etching tracks and electrodes on the substrate to form the transduction elements;
and folding the substrate to allow the transduction elements to interact;
whereby electro-magnetic and electro-static fields are generated allowing sensing or actuating of physical phenomenon.

2. A method of fabricating a magnetic sensor comprising:
Providing a flexible electronics substrate to form a set of planar coil element and bending them to face one another as in claim 1
whereby displacement between the two coils can be measured as induction change

3. A method of fabricating a magnetic sensors comprising:
Providing a flexible electronics substrate as in claim 1, to form wound coils
whereby the coil can be used to detect variations in a magnetic field.

4. A method of fabricating a magnetic actuator comprising:
Providing a flexible electronics substrate to form a set of planar coil element and bending them to face one another as in claim 1
whereby applying a current in the coils induces an electromagnetic force between the coils.

5. A method of fabricating a magnetic actuator comprising:
Providing a flexible electronics substrate as in claim 1, to form wound coils
whereby the coil can be used to generate magnetic field and therefore induce a force on a magnetic object.

6. A method of fabricating an electrostatic sensors comprising:
Providing a flexible electronics substrate to form a set of electrode elements and bending them to face one another as in claim 1
whereby displacement between the two electrodes can be measured as capacitance change

7. A method of fabricating an electrostatic actuator comprising:
Providing a flexible electronics substrate to form a set of electrode elements and bending them to face one another as in claim 1
whereby applying a potential on the electrodes will induce an electrostatic force between them to give actuation

8. A method of fabricating transducers in flexible electronics comprising:
Providing a 3D physical structure;
providing a flexible electronics panel
using a sheet metal design module to design and visualizing the wrapping of the flexible electronics panel around the mechanical structure;
and extracting the flat panel design file into a standard layout editor in order to process the flat panel;
whereby a 3D structure can be formed by wrapping the processed flat panel around the core.

9. A method of fabricating a magnetic sensor in flexible electronics comprising:
Providing a pre-machined magnetic core;
and providing a flexible electronics panel produced as in claim 9
whereby changes in the magnetic properties of the core can be measured (as induction) using the flexible electronics (windings).

10. A method of fabricating a magnetic actuator in flexible electronics comprising:
Providing a pre-machined magnetic core;
and providing a flexible electronics panel produced as in claim 9
whereby a magnetic field can be induced in the core by the flexible electronics to produce a magnetic force and hence actuation.

11. A method of determining the wiring layout of a mechatronic structure comprising;
Providing one or more mechanical structures in a modern CAD tool;
Designing the flexible electronics for the structure in a modern CAD tool;
Using a sheet metal design module of the modern CAD tool to wrap the flexible electronics around the mechanical structures;
Extracting the flat panel design file to a layout editor;
And auto-routing the connections and components;
Whereby the panel edge, bending vias and wiring-location determination is made using the layout editor rather than manually.

12. A method of manufacturing a layered transducer comprising;
Designing the structures in a CAD layout tool as outlined in claim 11 above;
using the sheet metal layout editor to ‘bend’ multiple layers of flexible electronics upon itself;
Designing the transducer out of these bent layers of flexible electronics;
whereby the layers either for complete transducer stacked upon one another or component layers of transducers

13. A method of manufacturing a layered transducer comprising;
Designing the structures in a CAD layout tool as outlined in claim 11 above;
using the sheet metal layout editor to ‘stack’ multiple layers of separate flexible electronics sheets;
Designing the transducer out of these stacked layers of flexible electronics;
whereby the layers either for complete transducer stacked upon one another or component layers of transducers

14. A method of making a magnetic core on flexible electronics comprising;
Providing electrodes of predetermined materials and processing on the flexible electronics;
and Electroplating magnetic material onto the electrodes;
Whereby the magnetic core is part of the flexible electronics, as opposed to being a discrete component.

15. A method of manufacturing a complete 3D mechatronic system comprising:
Providing flexible substrates of predetermined physical size and rigidity;
Etching conductive lines;
Folding the flexible substrates at predetermined angles and lengths;
Whereby the flexible substrates provide 5-100% of the mechanical rigidity, structure, and support of the complete 3D mechatronic system.
